(19) United States
(12) Patent Application Publication
(10) Pub. No.: US 2010/0332932 A1
(43) Pub. Date: Dec. 30, 2010

(54) TEST METHOD, TEST CONTROL PROGRAM AND SEMICONDUCTOR DEVICE

(75) Inventor: Hiroyuki MURAOKA, Kanagawa (JP)

Correspondence Address: YOUNG & THOMPSON, 209 Madison Street, Suite 500, Alexandria, VA, 22314, US

(73) Assignee: NEC ELECTRONICS CORPORATION, Kanagawa (JP)

(21) Appl. No.: 12/774,002

(22) Filed: May 5, 2010

(30) Foreign Application Priority Data
Jun. 25, 2009 (JP) 2009-150533

(51) Int. Cl. G01R 31/3177; G06F 11/25

(52) U.S. Cl. 714/744; 714/E11.155

(57) ABSTRACT

In a method of performing a test on a logic circuit in accordance with an exemplary aspect of the present invention, the test is performed by supplying a clock signal from a clock supply circuit to a plurality of clock domains operating by a clock signal of a same frequency. The method includes calculating a number of test patterns of each of the plurality of internal clock domains; classifying the plurality of clock domains into a plurality of groups based on the calculated number of test patterns; and assigning a clock supply circuit independently to each of the groups into which the clock domains are classified.

### INCORPORATION BY REFERENCE

This application is based upon and claims the benefit of priority from Japanese patent application No. 2009-150533, filed on Jun. 25, 2009, the disclosure of which is incorporated herein in its entirety by reference.

### BACKGROUND

1. Field of the Invention

The present invention relates to a test method, a test control program and a semiconductor device. In particular the present invention relates to a test method using a clock signal, a test control program performing the test method and a semiconductor device including a function of the test.

2. Description of Related Art

In the field of designing a test circuit of a semiconductor device, the test cost has risen because scale of test circuit has become large and the test patterns have increased. Accordingly, shortening of a test pattern length, that makes the test cost reduction, has been desired

Japanese Unexamined Patent Application Publication No. 2007-212339 discloses a test circuit which performs shortening of the test pattern length. A content of Japanese Unexamined Patent Application Publication No. 2007-212339 is explained with reference to FIGS. 8 and 9.

FIG. 8 is a flowchart of a procedure of adding a DFT (Design For Test) circuit in Japanese Unexamined Patent Application Publication No. 2007-212339. For example, the processings in the flowchart are executed with the apparatus such as a computer.

First, a computer acquires the first circuit information (for example, information on a circuit before the insertion of a DFT circuit (hereinafter called “DFT circuit pre-insertion circuit information”)) (step S501). Next, the computer extracts an internal clock domain based on the DFT circuit pre-insertion circuit information (step S502). The computer adds a selector(s) for supplying a scan clock signal to the DFT circuit pre-insertion circuit information (step S503).

Next, the computer acquires the second circuit information (for example, test frequency information). The test frequency information is clock frequency information that is supplied to each of internal clock domains in a functional test. The test frequency information acquired in step S504 is stored in a test frequency storage area M1. Further, the computer extracts a data-path dependency relation between the internal clock domains extracted in step S502, and stores the extracted information in a data-path dependency relation storage area M2 (step S505). Further, the computer generates the first information (for example, frequency group) based on the internal clock domain extracted in step S502 and information stored in a test frequency storage area M1 (step S506). The frequency group information is the grouped internal domains in which the functional test is performed based on a clock of the same frequency. The Frequency group information is stored in a frequency group storage area M3.

Next, based on the information in the data-path dependency relation storage area M2 and the information in the frequency group storage area M3, the computer generates the second group (for example, frequency subgroup) information (step S507). The frequency subgroup information is obtained by grouping internal clock domains in which each internal clock domain can operate independently of the other internal clock domains among the internal clock domains belonging to the same frequency group. That is, the frequency subgroup is obtained by grouping internal clock domains into subgroups so that internal clock domains belonging to one subgroup have no data-path dependency relation with internal clock domains belonging to the other subgroups among the internal clock domains belonging to the same frequency group.

The frequency subgroup information obtained in step S507 is stored in a frequency subgroup storage area M4. The computer adds the control circuit that controls a scan clock signal used in a functional test based on the information in the frequency group storage area M3 and the information in the frequency subgroup storage area M4 and a scan clock supply terminal SCKᵢₙ for supplying a scan clock signal to the DFT circuit pre-insertion circuit information (step S508). For example, the same numbers of the control circuits as the number of frequency groups are added. The same numbers of scan clock supply terminals SCKᵢₙ as the number of the added control circuits are also added. Based on the information in the frequency group storage area M3, the information in the frequency subgroup storage area M4, the information about the added control circuit, the scan clock supply terminal SCKᵢₙ, and the selector, the computer generates information in which the scan clock supply terminal SCKᵢₙ, the control circuit, the selector, and the internal clock domains are connected each other (step S509).

In step S509, the computer generates circuit information in which a DFT circuit including the scan clock supply terminal SCKᵢₙ, the control circuit and the selector is added. The circuit information is output as the third circuit information (for example, information on a circuit after the insertion of a DFT circuit (hereinafter called “DFT circuit post-insertion circuit information F3”)) (step S510).

Next, an example of the configuration of a semiconductor apparatus in which the DFT circuit is added is explained with reference to FIG. 9. As shown in FIG. 9, the internal clock domains 21 to 27 are grouped based on the data-path dependency relation and the test frequency. In the example of the configuration shown in FIG. 9, based on the test frequency, the first frequency group FG1 includes the internal clock domains 21 and 22; the second frequency group FG2 includes the internal clock domains 23, 24 and 25; and the third frequency group FG3 includes the internal domains 26 and 27. Further, according to the data-path dependency relation, the internal clock domain 21 is put in a frequency subgroup FSG101, and the internal clock domain 22 is put in a frequency subgroup FSG102. The internal clock domain 23 is put in a frequency subgroup FSG201, and the internal clock domains 24 and 25 are put in a frequency subgroup FSG202. The internal clock domain 26 is put in a frequency subgroup FSG301, and the internal clock domain 27 is put in a frequency subgroup FSG302.

Each of the internal clock domains 21 to 27 is connected with the selectors 301 to 307 respectively. Each of the selectors 301 to 307 has a “1” input terminal and a “0” input terminal. Each of the selectors outputs one of signals input to the terminals based on an externally input test mode control signal AMC. For example, when the test mode control signal AMC is “1”, the selector outputs a signal input to the “1” input terminal. When the test mode control signal AMC is “0”, the selector outputs a signal input to the “0” input terminal. Further, each of the selectors 301 to 307 is supplied with a scan clock signal from a corresponding control circuit to the “1” input terminal, and with an internal clock signal to the “0” input terminal.

The control circuits 401 to 403 are arranged so as to correspond to the first to third frequency groups. Further, each of the control circuits 401 to 403 connects the scan clock supply terminal SCKᵢₙ, a control terminal inputting a test control signal (for example, scan mode control signal SMC), and a control terminal inputting a selection signal (for example, frequency subgroup selection signal FreqSubCTL). Further, the circuits 401 to 403 have scan clock output terminals SCK₁ to SCKₙ (n represents the number of frequency subgroups in a corresponding frequency group).

Next, the connection between the control circuits and the selectors is described. The scan clock output terminal SCK₁ of the control circuit 401 supplies a scan clock signal to the internal clock domain 21 through the selector 301. The scan clock output terminal SCK₂ of the control circuit 401 supplies a scan clock signal to the internal clock domain 22 through the selector 302.

The control circuit 402 supplies a scan clock signal to the internal clock domain 23 through the selector 303 from the scan clock output terminal SCK₁. The scan clock output terminal SCK₂ of the control circuit 402 supplies a scan clock signal to the internal clock domain 24 through the selector 304. Further, a scan clock signal is supplied to the internal clock domain 25 through the selector 305

The scan clock output terminal SCK₁ of the control circuit 403 supplies a scan clock signal to the internal clock domain 26 through the selector 306. The scan clock output terminal SCK₂ of the control circuit 403 supplies a scan clock signal to the internal clock domain 27 through the selector 307.

### SUMMARY

In the semiconductor device disclosed in the above related arts, the internal domains are grouped and the frequency group is generated according to the test frequency. Further, the frequency subgroup is obtained by grouping internal clock domains that each internal clock domains can operate independently of the other internal clock domains among the internal clock domains belonging to the same frequency group. Further, the same number of control circuits as the number of frequency groups are added, and the same number of scan clock supply terminals SCKᵢₙ as the number of the added control circuits are added.

Therefore, in the semiconductor device disclosed in the above related arts, a scan clock signal supplied only to one frequency subgroup among all the frequency subgroups put in a group of the same frequency. As a result, the test pattern length is the sum of a number of test patterns each of which is generated by performing a test on one of the frequency subgroups, resulting in a problem that the test pattern length becomes longer.

A first exemplary aspect of the present invention is a method of performing a test on a logic circuit, the test being performed by supplying a clock signal from a clock supply circuit to a plurality of clock domains operating by a clock signal of a same frequency, the method including: calculating a number of test patterns of each of the plurality of clock domains; classifying the plurality of clock domains into a plurality of groups based on the calculated number of test patterns; and assigning a clock supply circuit independently to each of the groups into which the clock domains are classified.

According to the above-described test method, a test pattern length can be shortened because tests can be performed on a plurality of clock domains operating with a clock signal of the same frequency at the same time using a plurality of clock supply circuits. In particular, since clock domains are classified into a plurality of groups based on the number of test patterns for each of a plurality of clock domains, the grouping can be carried out so that the overall test pattern length is shortened.

A second exemplary aspect of the present invention is a storage medium storing a program for causing a computer to perform a test on a logic circuit by supplying a clock signal from a clock supply circuit to a plurality of clock domains operating with a clock signal of a same frequency, the program causing to the computer to: calculate a number of test patterns of each of the plurality of clock domains; classify the plurality of clock domains into a plurality of groups based on the calculated number of test patterns; assign a clock supply circuit independently to each of the groups into which the clock domains are classified; and supply the clock signal from the clock supply circuit to the groups into which the clock domain is classified.

According to the above-described program, a test pattern length can be shortened because tests can be performed on a plurality of clock domains operating with a clock signal of the same frequency at the same time using a plurality of clock supply circuits. In particular, since clock domains are classified into a plurality of groups based on the number of test patterns for each of a plurality of clock domains, the grouping can be carried out so that the overall test pattern length is shortened.

A third exemplary aspect of the present invention is a semiconductor device including a first clock domain and a second clock domain operating with a clock signal of a same frequency, including: a first clock supply circuit that supplies a test clock to the first clock domain; a second clock supply circuit that supplies a test clock to the second clock domain; a first terminal that inputs a test clock to the first clock supply circuit; and a second terminal that inputs a test clock to the second clock supply circuit.

According to the above-described semiconductor device, a test pattern length can be shortened because tests can be performed on a plurality of clock domains operating with a clock signal of the same frequency at the same time using a plurality of clock supply circuits. In particular, since the semiconductor device has the first terminal and the second terminal, it is easy to change the operating mode between a mode to shortening the test pattern length and a mode to maintain the fault detection rate.

The present invention can provide, in an exemplary aspect, a test method capable of shortening the test pattern length, a test control program and a semiconductor device.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a flowchart of a procedure of adding a DFT circuit in accordance with a first exemplary aspect of the present invention;

FIG. 2 is a flowchart of grouping a clock supply circuit in accordance with a first exemplary aspect of the present invention;

FIG. 3 is a flowchart of reclassification of a frequency subgroup in accordance with a first exemplary aspect of the present invention;

FIG. 4 is a configuration diagram of a semiconductor device in accordance with a first exemplary aspect of the present invention;

FIG. 5 is a flowchart of grouping a clock supply circuit in accordance with a second exemplary aspect of the present invention;

FIG. 6 is a flowchart of reclassification of a frequency subgroup in accordance with a second exemplary aspect of the present invention;

FIG. 7 is a configuration diagram of a computer system including a semiconductor device in accordance with a first and a second exemplary aspect of the present invention;

FIG. 8 is a flowchart of a procedure of adding a DFT circuit of the related art; and

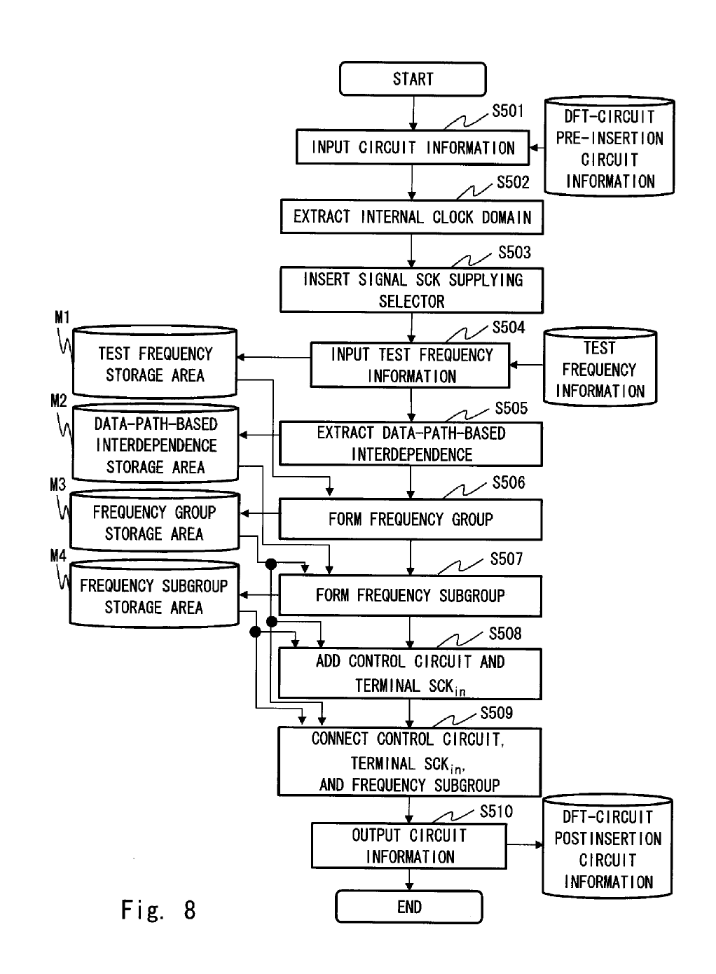

FIG. 9 is a configuration diagram of a semiconductor device of the related art.

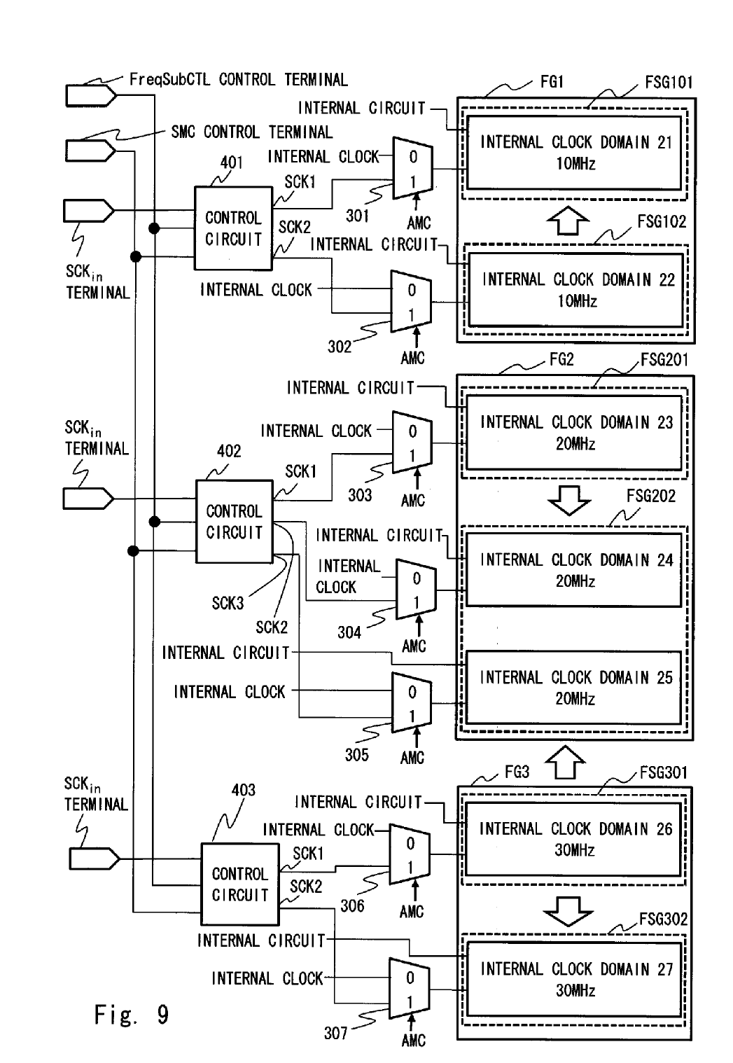

### DETAILED DESCRIPTION OF THE EXEMPLARY EMBODIMENTS

### First Exemplary Embodiment

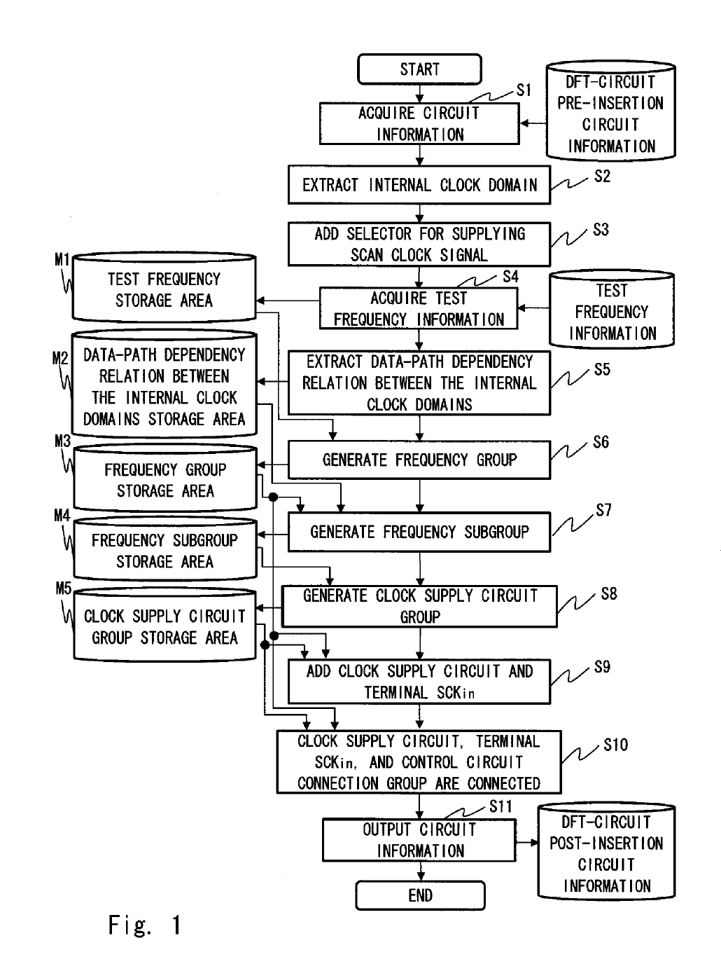

Exemplary embodiments of the present invention are explained hereinafter with reference to the drawings. A processing flow of adding a DFT circuit in accordance with a first exemplary aspect of the present invention is explained with reference to FIG. 1. The processing shown in FIG. 1 is executed with, for example, a computer or a similar apparatus.

First, a computer acquires the first circuit information (for example, information on a circuit before the insertion of a DFT circuit (hereinafter called “DFT circuit pre-insertion circuit information”)) (step S1). Next, the computer extracts an internal clock domain(s) based on the DFT circuit pre-insertion circuit information (step S2). The internal clock domain is composed of a logic circuit that operates by a clock signal of the same frequency. The internal clock domain may be composed of a plurality of logic circuits or a single logic circuit. Next, based on the information of the internal clock domain extracted in step S2, the computer adds a selector for supplying a scan clock signal to the DFT-circuit pre-insertion circuit information (step S3). For example, the selector is arranged for each internal clock domain.

Next, the computer acquires the second circuit information (for example, test frequency information) (step S4). The test frequency information is the clock frequency information that is supplied to each internal clock domain in a functional test. The test frequency information acquired in step s4 is stored in a test frequency storage area M1. Next, the computer extracts a data-path dependency relation between the internal clock domains extracted in step S2. The extracted information is stored in a data-path dependency relation storage area M2 (step S5). The data-path dependency relation is relational information indicating that a certain internal clock domain operates based on a signal output from another internal clock domain. Further, based on the information of the internal clock domain extracted in step S2 and the information of the test frequency storage area M1, the computer generate first group information (for example, frequency group information) (step S6). The frequency group information is grouping information indicating that the internal clock domains are grouped based on their clock frequency so that internal clock domains that operate at the same frequency are put in the same group. The generated frequency group information is stored in a frequency group storage area M3.

Next, based on the information in a data-path dependency relation storage area M2 and the information in frequency group storage area M3, the computer generates the information of the second group (for example, frequency subgroup) obtained by grouping the internal clock domains that can operate independently among the internal clock domains belonging to the same frequency group (step S7). That is, the frequency subgroup information is obtained by grouping the internal clock domains into subgroups so that internal clock domains belonging to one subgroup have no data-path dependency relation with internal clock domains belonging to the other subgroups among the internal clock domains belonging to the same frequency group. The frequency subgroup information generated in step S7 is stored in the frequency subgroup storage area M4.

Next, based on the information in frequency subgroup storage area M4, the computer generates the third group (for example, clock supply circuit group) information (step S8). The clock supply circuit group information is grouping information indicating a plurality of frequency groups to which the scan clock signal is supplied from a single clock supply circuit. The clock supply circuit group information generated in step S8 is stored in a clock supply circuit group storage area M5.

Next, the computer adds the clock supply circuit and a SCKᵢₙ terminal to the DFT circuit pre-insertion circuit information based on the clock supply circuit group information in the clock supply circuit group storage area M5 and the frequency group information in the frequency group storage area M3 (step S9). The SCKᵢₙ terminal supplies the scan clock signal to the clock supply circuit. The same number of clock supply circuits and the SCKᵢₙ terminals as the number of the clock supply circuit groups are added (step S9).

Next, based on the information in the frequency group storage area M3, the information in the clock supply circuit group storage area M5, the added clock supply circuit, the scan clock supply terminal SCKᵢₙ, and the selector, the computer generates the circuit information in which the scan clock supply terminal SCKᵢₙ, the clock supply circuit, the selector, and the internal clock domain are connected (step S10).

In step S10, the computer generates the circuit information in which the DFT circuit including the selector, the scan clock supply terminal SCKᵢₙ, and the clock supply circuit is added. The computer outputs the circuit information as the third circuit information (for example, information on a circuit after the insertion of a DFT circuit (hereinafter called “DFT circuit post-insertion circuit information F3”)) (step S10).

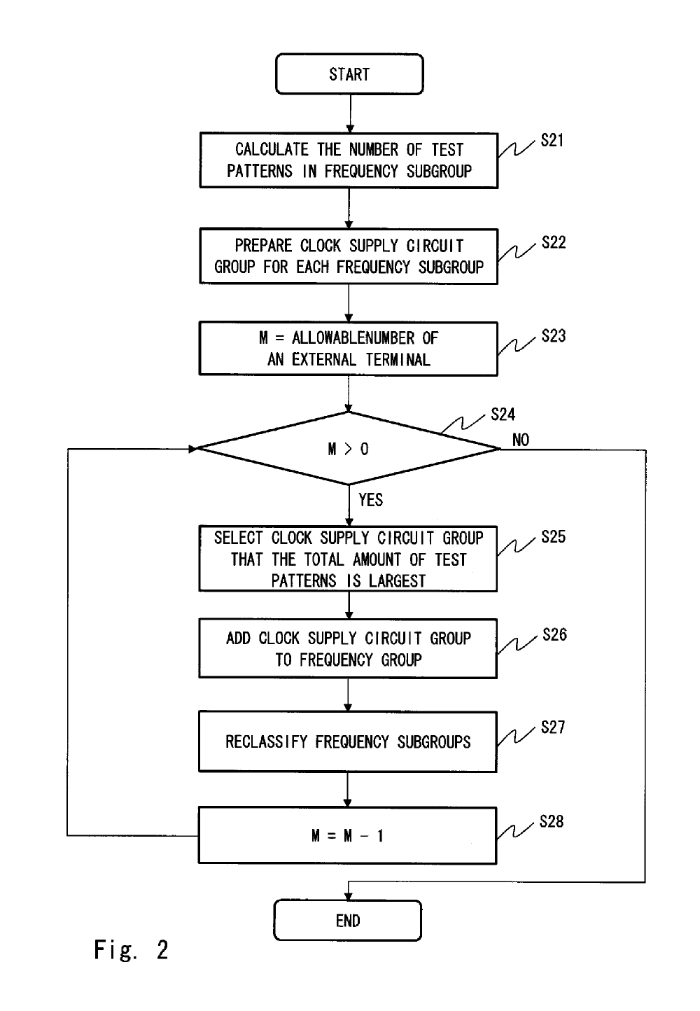

Subsequently, the details of a processing flow for generating the clock supply circuit group performed in step S8 of FIG. 1 in accordance with a first exemplary aspect of the present invention is explained with reference to FIG. 2.

First, the computer calculates the number of test patterns in each frequency subgroup (step S21). The number of test patterns in each frequency subgroup is the number of test patterns that are generated when the scan clock signal is supplied only to that frequency subgroup. For example, the test patterns of each frequency subgroup are generated automatically by ATPG (Automatic Test Pattern Generation).

Next, the computer prepares the clock supply circuit group for each frequency subgroup, and classifies all the frequency subgroups into the clock supply circuit groups according to the test frequency so that frequency subgroups of the same test frequency are put in the same clock supply circuit group (step S22). Next, the computer sets an allowable number of an external terminal to a variable M (step S23). The allowable number of an external terminal is the number of terminals to which the SCKᵢₙ terminals can be added. For example, the number of terminals to which the SCKᵢₙ terminals can be added is determined based on the area of the circuit board or the scale of the circuit formed on the circuit board.

Next, the computer determines whether or not the value M is greater than 0 (step S24). When the value M is 0, the computer finishes the process. When the value M is greater than 0, the process of step S25 is executed by the computer.

Next, when the computer determines that the value M is greater than 0, the computer selects the frequency group in which the total amount of test patterns calculated for each clock supply circuit group in step S21 is largest (hereinafter called “the number of test patterns of clock supply circuit group”) (step S25). When there is only one clock supply circuit group in each frequency group, the computer selects that clock supply circuit group.

Next, the computer adds one new clock supply circuit group to the frequency group corresponding to the clock supply circuit group selected by step S25 (step S26). Then, the computer reclassifies the frequency subgroups in the clock supply circuit groups selected in step S25 into the clock supply circuit groups including the clock supply circuit groups selected in step S25 and the clock supply circuit group added in step S26 (step S27).

Next, the computer subtracts 1 from the value M (step S28). Next, the computer returns to step S24, and repeats the process of step S24 to S28 as long as the value M is greater than 0. That is, the computer repeats the process of step S24 to s28 until the value M becomes 0.

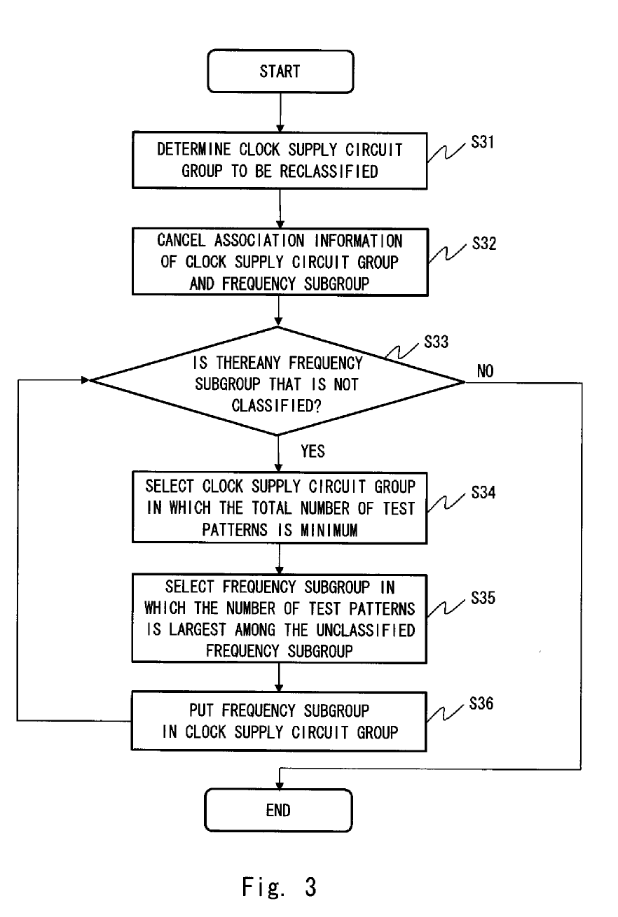

Next, details of a processing flow for reclassifying the frequency subgroup performed in step S27 of FIG. 2 in accordance with a first exemplary aspect of the present invention is explained with reference to FIG. 3. First, the computer extracts the specific clock supply circuit group (hereinafter called “clock supply circuit group to be reclassified”) (step S31). The specific clock supply circuit group is all the clock supply circuit groups possessed by the frequency group to which one clock supply circuit is newly added.

Next, the computer cancels the relation between the frequency subgroup and the clock supply circuit group to be reclassified (step S32).

Next, the computer determines whether or not there is any frequency subgroup that is not classified into the clock supply circuit groups (step S33). Immediately after adding the new clock supply circuit group into the frequency group, all the frequency groups are not classified into the clock supply circuit groups. When there is no unclassified frequency subgroup, that is, every frequency subgroup is classified into a control circuit connection groups, the computer finishes the process. When there is unclassified frequency subgroup, the computer executes the process of step S34.

Next, when the computer determines that there is unclassified frequency subgroup, the computer compares the total number of frequency subgroup test patterns calculated for each clock supply circuit group. Further, the computer selects the clock supply circuit group in which the total number of test patterns is minimum (step S34). Immediately after adding the new clock supply circuit group to the frequency subgroup, any frequency subgroup is not classified into the clock supply circuit group. Therefore, the number of test patterns for each clock supply circuit group is 0. In this case, the computer may select any clock supply circuit group. When there are a plurality of clock supply circuit groups for which the number of the test patterns of the clock supply circuit group is the same, the computer may select any clock supply circuit group among the plurality of clock supply circuit groups.

Next, the computer selects the frequency subgroup in which the number of test patterns is largest among the unclassified frequency subgroups (step S35). Next, the computer classifies the frequency subgroup selected in step S35 into the clock supply circuit group selected in step S34 (step S36). Next, returning to step S33, the computer repeats the process of step S33 to step S36 until there is no unclassified frequency subgroup.

When executing a process of above-mentioned FIGS. 1 to 3, all the frequency subgroups are related to the clock supply circuit group.

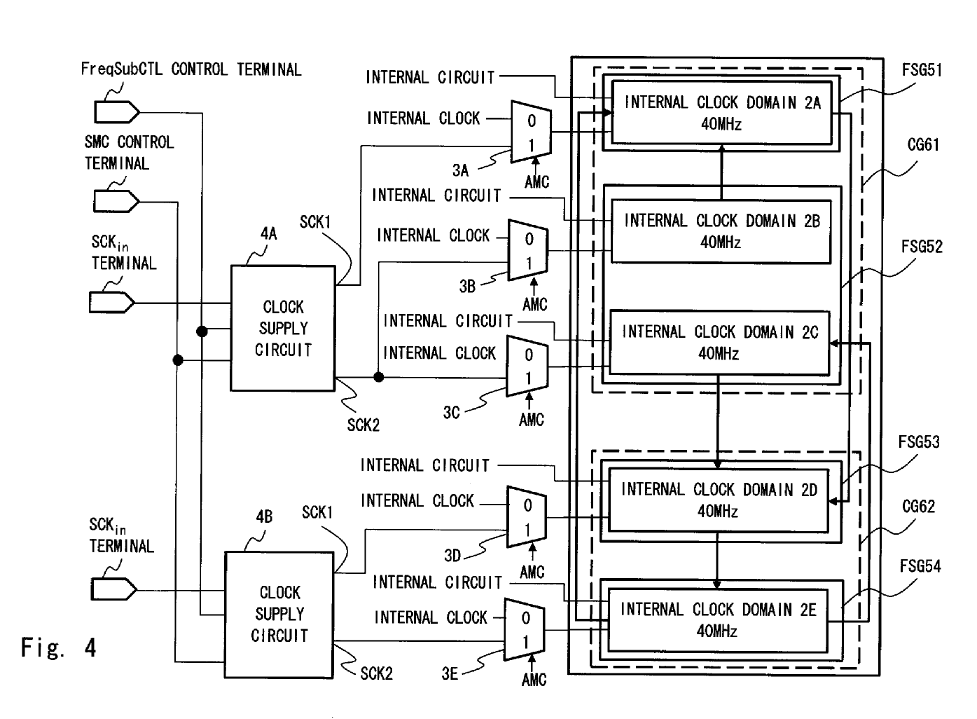

Next, a configuration of circuit in which the clock supply circuit is inserted according to the process of adding clock supply circuit in FIGS. 1 to 3 is explained with reference to FIG. 4. The circuit shown in FIG. 4 includes the internal clock domains 2A to 2E, selectors 3A to 3E, and the clock supply circuits 4A and 4B.

The internal clock domains 2A to 2E are operating with the same frequency clock. For example, the internal clock domains 2A to 2E are operating at a frequency of 40 MHz.

A data-path dependency relation of internal clock domains 2A to 2E is explained. For example, the data-path dependency relation is relational information indicating that the internal clock domain 2A is operating based on a signal input from the internal clock domain 2B. A specific example of the data-path dependency relation of the inter clock domains 2A to 2E is explained hereinafter. For example, the internal clock domain 2A is operating based on signal input from internal clock domains 2B and 2E, and outputs a signal to the internal clock domain 2D. Further, the internal clock domain 2C is operating based on signal input from the internal clock domain 2E, and outputs the signal to the internal clock domain 2D. Further, the internal clock domain 2D is operating based on signal input from the internal clock domains 2A and 2C, and outputs the signal to the internal clock domain 2E. Further, the internal clock domain 2E is operating based on signal input from the internal clock domain 2D, and outputs the signal to the internal clock domains 2A and 2C.

When the internal clock domains include the above-mentioned the data-path dependency relation, the internal clock domain 2A is put in the frequency subgroup (FSG) 51, the internal clock domains 2B and 2C is put in FSG 52, the internal clock domain 2D is put in FSG53 and the internal clock domain 2E is put in FSG 54.

Further, FSG 51 and FSG 52 are put in a clock supply circuit group (CG) 61, and FSG 53 and FSG54 are put in CG 62. FSG 51 to FSG54 are classified so that the numbers of the test patterns of CG 61 and CG 62 get closer to each other.

Each of the internal clock domains 2A to 2E is connected with respective one of the selectors 3A to 3E. Each of the selectors 3A to 3E has a “1” input terminal and a “0” input terminal. Each of the selectors outputs one of signals input to the terminal based on an externally input test mode control signal AMC. For example, when the test mode control signal AMC is “1”, the selector 3A to 3E output a signal input to the “1” input terminal to the internal clock domains. When the test mode control signal AMC is “0”, the selectors 3A to 3E output a signal input to the “0” to the internal clock domains. Each of the selectors 3A to 3E is supplied with a scan clock signals from a control circuit to the “1” input terminal, and with an internal clock signal to the “0” input terminal.

The clock supply circuits 4A to 4B are arranged so as to correspond to CG 61 and CG 62. Further, each of the clock supply circuits 4A and 4B connects the scan clock supply terminal SCKᵢₙ, a control terminal inputting a test control signal (for example, scan mode control signal SMC), and a control terminal inputting a selection signal (for example, frequency subgroup selection signal FreqSubCTL). Further, clock supply circuits 4A and 4B have scan clock output terminals SCK₁ to SCKₙ (n represents the number of frequency subgroups in a corresponding frequency group). For example, in the functional test of the internal clock domains, the scan mode control signal SMC controls a shift cycle in which data is shifted and a cycle in which data is captured.

The clock supply circuit 4A outputs the scan clock signal supplied from the SCKᵢₙ terminal to each frequency subgroup. For example, when the clock supply circuit 4A outputs a scan clock signal to FSG51 through a SCK 1 terminal, the clock supply circuit 4A does not output a scan clock signal to FSG 52. When the clock supply circuit 4A outputs a scan clock signal to FSG 52 through a SCK 2 terminal, the clock supply circuit 4A does not output a scan clock signal to FSG 51. The clock supply circuit 4B performs similar control.

Next, the functional test method based on the circuit structure explained in FIG. 4 is explained. The clock supply circuits 4A and 4B output the scan clock signal supplied from SCKᵢₙ terminal to frequency subgroups. The frequency subgroup to which the scan clock signal is output is the subgroup selected by frequency subgroup select signal FreqSubCTL. Because the clock supply circuits 4A and 4B operate independently, the clock supply circuits 4A and 4B supply the scan clock signal to FSG 51 and FSG 53 at the same time. Further, the clock supply circuits 4A and 4B can supply the scan clock signal at the same time for the combination of FSG 51 and FSG 54, FSG 52 and FSG 53, or FSG 52 and FSG 54.

The processing in which the scan clock signal is supplied to FSG 51 and FSG 53, or FSG 52 and FSG 54 is explained. First, the clock supply circuits 4A and 4B supply the scan clock signal to FSG 51 and FSG 53, or FSG 52 and FSG 54. After the functional tests of FSG 51 and FSG 53 have completed, the clock supply circuits 4A and 4B supply the scan clock signal to FSG 52 and FSG 54. Hereby, the test pattern length used to test the internal clock domains 2A to 2E is calculated by adding the number of test patterns for FSG 52 or FSG 54 to the number of test patterns for FSG 51 or FSG 53.

As explained above, in the test method according to the first exemplary embodiment of the present invention, the test pattern length is reduced. As shown FIG. 4, when the same frequency group has FSGs 51 to 54, the test is executed by using one clock supply circuit and test pattern length is calculated by adding the numbers of test patterns for the respective frequency subgroups. Namely, when only one clock supply circuit is arranged, more than one frequency subgroup cannot be tested at the same time. Therefore, the test pattern length is calculated by adding the numbers of test patterns for the respective frequency subgroups.

In contrast, as the first exemplary embodiment of the present invention, when two clock supply circuits are arranged for the same frequency group, the test is executed at the same time for two frequency subgroups. Therefore, compared to arranging only one clock supply circuit, test pattern length is shortened by about half. The number of the clock supply circuits arranged for the same frequency group is not limited to 2, and a plurality of clock supply circuits can be arranged.

Further, the test pattern length of all the circuits is shortened by classifying the frequency subgroups so that the test pattern lengths of frequency subgroups belonging to the clock supply circuit group get closer to each other.

### Second Exemplary Embodiment

A semiconductor device in accordance with a second exemplary aspect of the present invention is different from a first exemplary embodiment in the information used for generating the clock supply circuit group in a semiconductor.

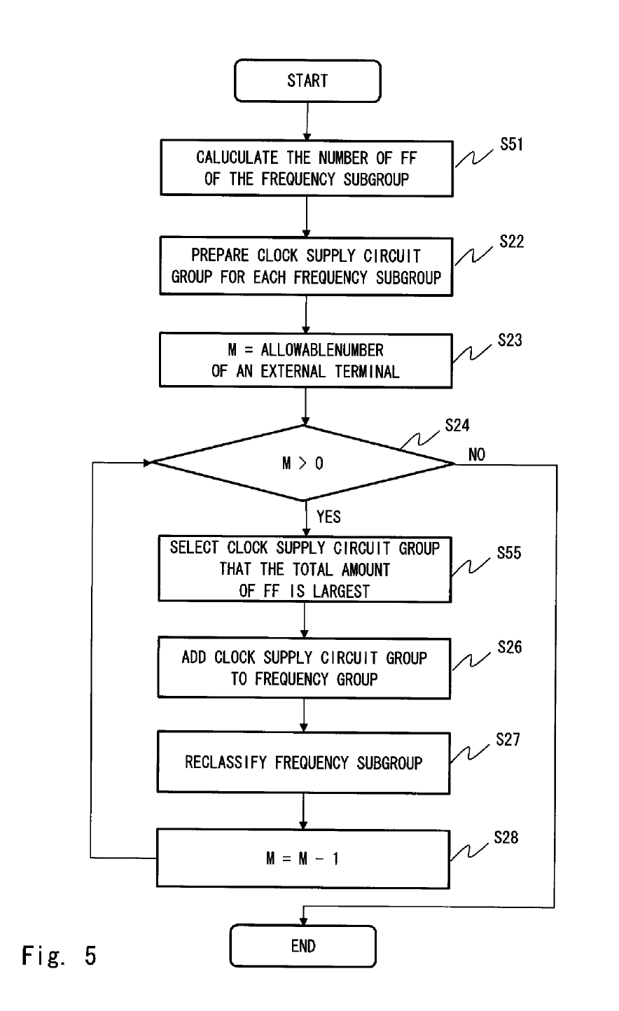

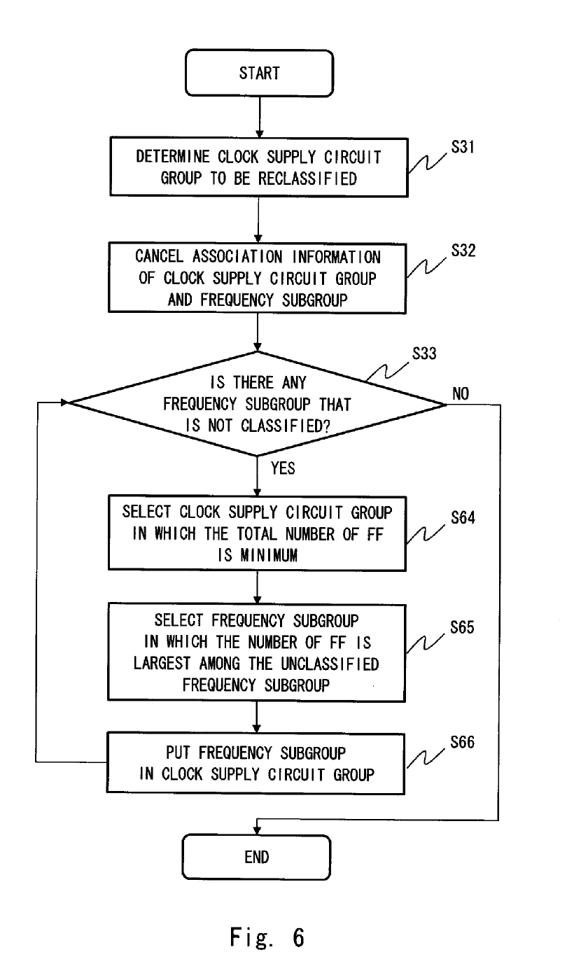

A processing flow for assembling a clock supply circuit group in accordance with a second exemplary aspect of the present invention is explained with reference to FIGS. 5 and 6. In FIG. 5 of a second exemplary embodiment, a step S51 is substituted for the step S21 of FIG. 2 and a step S55 is substituted for the step S25. The other processing is similar to the processing of FIG. 2.

In step S51, the computer calculates the number of flip flop circuits of the frequency subgroup. Specifically, the computer calculates the number of flip flop circuits included in a logic circuit that constitutes the internal clock domain. In step S55, the computer selects a clock supply group including more flip flop circuits than any other clock supply groups. In step S55, the computer determines the frequency group to which the clock supply circuit is to be added based on the number of flip flop circuits.

Next, in a second exemplary embodiment, steps S64 and S65 in FIG. 6 are substituted for the step S34 and step S35 in FIG. 3. The other processing is similar to the processing of FIG. 3.

In step S64, the computer selects the clock supply circuit group in which the number of flip flop circuits is smallest. In step S65, the computer selects frequency subgroup having the largest number of flip flop circuits among unclassified frequency subgroups. In step S36, the computer assigns the frequency group selected by step S65 to the clock supply circuit selected in step S64. In this way, the computer assigns the frequency subgroup to the clock supply circuit based on the number of flip flop circuits.

As explained above, the clock supply circuit group assembling method according to the second exemplary embodiment of the present invention makes it possible to perform the test using the clock supply circuit group classified based on the number of flip flop circuits. For example, generating the test patterns in frequency subgroup needs to generate test patterns by ATPG processing. Therefore, the calculating process to obtain the number of test patterns is longer. In the second exemplary embodiment of the present invention, the number of flip flop circuits is used instead of the number of test patterns. In general, the larger the number of flip flop circuits is, the larger the number of test patterns becomes. Further, calculating the number of flip flop circuits is shorter in processing time than generating the test patterns. Therefore, the number of flip flop circuits is used instead of the number of test patterns to generate the clock supply circuit group.

### Third Exemplary Embodiment

A test method in accordance with a third exemplary aspect of the present invention is explained with reference to FIG. 4. In the circuit in FIG. 4, an SCKᵢₙ terminal is connected to each of clock supply circuits 4A and 4B. Therefore, the test in which the clock supply circuit 4A is supplied with the scan clock signal and the clock supply circuit 4B is not supplied with the scan clock signal can be performed. Namely, a selection can be made so that both clock supply circuits 4A and 4B are supplied with the scan clock signal, or either of the clock supply circuits 4A or 4B is supplied with the scan clock signal. The scan clock signal may be supplied in a state where the control circuit is connected to the SCKᵢₙ terminal and either one of SCKᵢₙ terminals is selected. Alternatively, the control circuit is connected to clock supply circuits 4A and 4B, so that only the scan clock signal that is supplied through either one of the SCKᵢₙ, terminals may be supplied to the frequency subgroup.

As explained above, the test method in accordance with the third exemplary of the present invention makes it possible to output the scan clock signal to CG 61 or CG 62 and to perform the test. In this way, for example, FSG 53 or FSG 54 having the data-path dependency relation with FSG 51 can be tested independently. Therefore, the test can be performed without decreasing the fault detection rate. Further, when scan clock signal is output to CG 61 and CG 62, test pattern length is shortened as in the case of the first exemplary embodiment. In this way, because the test method can be selected, an appropriate test method can be selected based on the circuit scale or circuit complexity.

The present invention may also be realized by the computer program to execute any process on a CPU (Central Processing Unit). The program can be stored and provided to a computer using any type of non-transitory computer readable media. Non-transitory computer readable media include any type of tangible storage media. Examples of non-transitory computer readable media include magnetic storage media (such as floppy disks, magnetic tapes, hard disk drives, etc.), optical magnetic storage media (e.g. magneto-optical disks), CD-ROM (compact disc read only memory), CD-R (compact disc recordable), CD-R/W (compact disc rewritable), and semiconductor memories (such as mask ROM, PROM (programmable ROM), EPROM (erasable PROM), flash ROM, RAM (random access memory), etc.). The program may be provided to a computer using any type of transitory computer readable media. Examples of transitory computer readable media include electric signals, optical signals, and electromagnetic waves. Transitory computer readable media can provide the program to a computer via a wired communication line (e.g. electric wires, and optical fibers) or a wireless communication line.

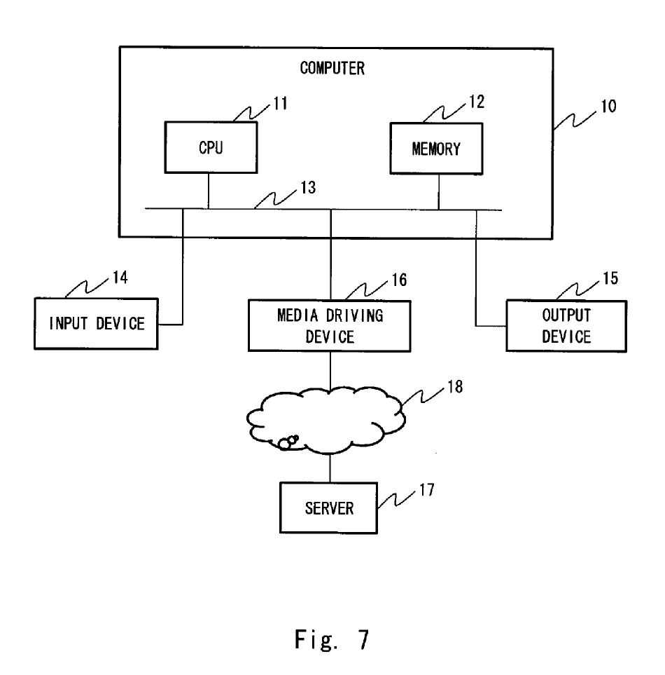

An example of the configuration of a computer system in which the program is transmitted via other communication media such as the Internet is explained with reference to the FIG. 7.

The computer system is constructed from a computer 10, an input device 14, an output device 14, a media driving device 16 and a server 17. The computer has a CPU 11, a memory 12 and a bus 13. The media driving device 16 and the server 1 is connected through a network 18.

CPU 11 executes programs in the memory 12 based on an input from input device 14. The computer outputs the executed result of the program to the output device 15. The media driving device 16 receives the program data signal transmitted from the server 18 through the network 18. The media driving device 16 stores the received program data in the memory 12 through the bus 13. Further, the media driving device 16 transmits the program data stores in the memory 12 to the server 18.

The above explanation is made only for explaining exemplary embodiments of the present invention, and the present invention is not limited to those exemplary embodiments. Further, various modifications, additions, and conversions can be easily made to any components of the above-described exemplary embodiments by those skilled in the art without departing from the scope of the present invention.

The first to third exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A method of performing a test on a logic circuit, the test being performed by supplying a clock signal from a clock supply circuit to a plurality of clock domains operating by a clock signal of a same frequency, the method comprising:
calculating a number of test patterns of each of the plurality of clock domains;
classifying the plurality of clock domains into a plurality of groups based on the calculated number of test patterns; and
assigning a clock supply circuit independently to each of the groups into which the clock domains are classified.

2. The method of performing a test on a logic circuit according to claim 1, wherein
the plurality of clock domains are classified into the plurality of groups so that the numbers of test patterns get closer to each other.

3. The method of performing a test on a logic circuit according to claim 2, wherein
the plurality of clock domains are classified into the groups in a descending order of the calculated number of test patterns for the clock domains.

4. The method of performing a test on a logic circuit according to claim 3, further comprising:
selecting a group having the smallest number of test patterns; and
classifying the clock domain into the selected group.

5. The method of performing a test on a logic circuit according to claim 1, wherein
the number of test patterns is calculated for each subgroup including the clock domain having no data-path dependency relation; and
the subgroup is classified into the groups based on the calculated number of test patterns.

6. The method of performing a test on a logic circuit according to claim 1, wherein
the number of the clock supply circuits to be assigned is determined according to the number of terminals for supplying a clock signal to the clock supply circuit that can be added.

7. The method of performing a test on a logic circuit according to claim 1, wherein
the number of test patterns are calculated based on a number of flip flop circuits included in the clock domain.

8. A non-transitory computer readable medium storing a program for causing a computer to perform a test on a logic circuit by supplying a clock signal from a clock supply circuit to a plurality of clock domains operating with a clock signal of a same frequency, the program causing to the computer to:
calculate a number of test patterns of each of the plurality of clock domains;
classify the plurality of clock domains into a plurality of groups based on the calculated number of test patterns;
assign a clock supply circuit independently to each of the groups into which the clock domains are classified;
supply the clock signal from the clock supply circuit to the groups into which the clock domain is classified.

9. The non-transitory computer readable medium that stores a program according to claim 8, wherein
the plurality of clock domains are classified into the plurality of groups so that the numbers of test patterns get closer to each other.

10. The non-transitory computer readable medium that stores a program according to claim 9, wherein
the plurality of clock domains are classified into the groups in a descending order of the calculated number of test patterns for the clock domains.

11. The non-transitory computer readable medium that stores a program according to claim 10, further comprising:
select a group having the smallest number of test patterns; and
classify the clock domain into the selected group.

12. A semiconductor device including a first clock domain and a second clock domain operating with a clock signal of a same frequency comprising:
a first clock supply circuit that supplies a test clock to the first clock domain;
a second clock supply circuit that supplies a test clock to the second clock domain;
a first terminal that inputs a test clock to the first clock supply circuit; and
a second terminal that inputs a test clock to the second clock supply circuit.
